(19) United States
(12) Patent Application Publication
(10) Pub. No.: US 2023/0065187 A1
(43) Pub. Date: Mar. 2, 2023

(54) STRUCTURE AND METHOD OF INCREASING SUBTRACTIVE BITLINE AIR GAP HEIGHT

(71) Applicant: Intel Corporation, Santa Clara, CA (US)

(72) Inventors: John Hopkins, Milpitas, CA (US); Nancy M. Lomeli, Boise, ID (US)

(21) Appl. No.: 18/047,094

(22) Filed: Oct. 17, 2022

(51) Int. Cl. H01L 21/768; H01L 23/535; H01L 23/532

(52) U.S. Cl. CPC H01L 21/7682; H01L 23/535; H01L 23/53214; H01L 23/53228; H01L 23/53257; H01L 23/5329

(57) ABSTRACT

Systems, apparatuses, and methods may provide for technology for forming extended air gaps for bitline contacts. For example, such technology patterns and etches a dielectric layer and a bitline layer to create bitline contacts in a memory die. An air gap dielectric layer is deposited to form an air gap between adjacent bitline contacts, and wherein the air gap has a height dimension that extends past a height dimension of the bitline contacts.

### TECHNICAL FIELD

Embodiments generally relate to memory structures. More particularly, embodiments relate to forming a an extended bitline air gap structure for a 3D-NAND memory structure.

### BACKGROUND

Three-dimensional (3D) NAND technologies are commonly used to create nonvolatile (NV) storage devices, such as solid state drives (SSDs). Reference to 3D NAND can more specifically refer to NAND flash.

NAND-type flash memory (“NAND memory”) may be organized into multiple cells, with each cell containing one or more bits of data and being accessible through an array of bit lines (columns) and word lines (rows). With 3D NAND processes, the storage array is often created with the word lines (WL) in a staircase structure, with vertical connector pillars connecting a top connection layer to the word lines.

Increased 3D NAND densities are achieved with smaller process geometries and feature spacing. With the increase of number of tiers or word lines in 3D NAND in every generation, the number of contacts is also going up, requiring more routing paths to hook up the contacts to corresponding complementary metal-oxide-semiconductor (CMOS) devices.

### BRIEF DESCRIPTION OF THE DRAWINGS

The various advantages of the embodiments will become apparent to one skilled in the art by reading the following specification and appended claims, and by referencing the following drawings, in which:

FIG. 1 is a block diagram of an example of a multi-deck non-volatile memory device according to an embodiment;

FIG. 2 illustrates an example side view diagram of a memory die according to an embodiment;

FIG. 3 is a current memory device bitline structure;

FIGS. 4-6 illustrate an example of a memory device bitline structure according to an embodiment at various stages of formation;

FIG. 7 is a flowchart of an example method of forming a memory device according to an embodiment;

FIG. 8 is an illustration of an example of a semiconductor package apparatus according to an embodiment; and

FIG. 9 is a block diagram of an example of a performance-enhanced computing system according to an embodiment.

### DESCRIPTION OF EMBODIMENTS

As will be descried in greater detail below, systems, apparatuses, and methods are described that provide for technology for forming an extended bitline air gap structure for a 3D-NAND memory structure, in some examples. For example, in some implementations described herein, an increased height bitline airgap is created during subtractive bitline formation using a dielectric layer (e.g., oxide, nitride, the like, and/or combinations thereof) on top of a bitline layer (e.g., bitline tungsten, aluminum, copper, molybdenum, the like, or combinations thereof), a subtractive bitline etch keeps the dielectric on top of remaining bitline contacts followed by an air gap dielectric layer deposition which will follow the height of the dielectric rather than the bitline contacts.

As used herein the term “air gap dielectric” refers to a dielectric that is non-conformal to the extent that air gaps are not filled during deposition. For example, such an air gap dielectric layer includes an air gap dielectric, an air gap nitride, an air gap oxide, an air gap silicon nitride, an air gap carbon doped silicon nitride, the like, and/or combinations thereof.

In operation, some implementations involve: depositing a bitline layer (e.g., bitline tungsten, aluminum, copper, molybdenum, the like, or combinations thereof) for a subtractive bitline structure, capping the bitline layer with a dielectric layer, patterning and etching the dielectric and the bitline layer to create subtractive bitline contacts, depositing an air gap dielectric to form an air gap which will follow the height of the dielectric and therefore be above where it otherwise would have been with the subtractive bitline contacts to improve the bitline RC (e.g., the time constant as a product of circuit resistance and circuit capacitance).

Advantageously, higher bitline airgaps, such as those disclosed herein, improve bitline capacitance.

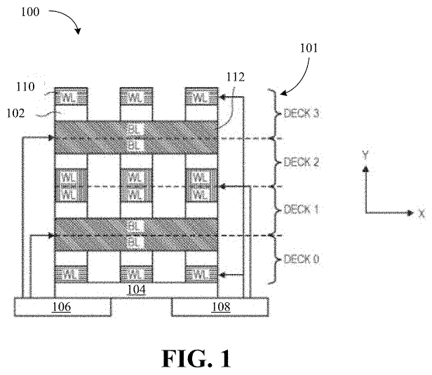

FIG. 1 is a simplified block diagram of an example of a memory device 100 according to an embodiment. As illustrated, the memory device 100 is a multi-deck non-volatile memory device including a plurality of decks 101 (e.g., Deck 0, Deck 1, Deck 2, and Deck 3, or the like).

In some implementations, each of the decks 101 may include an array of memory cells 102 with conductive access lines (e.g., word lines 110 and bitlines 112). For example, the memory cells 102 may include a material capable of being in two or more stable states to store a logic value. In one example, the memory cells 102 may include a phase change material, a chalcogenide material, the like, or combinations thereof. However, any suitable storage material may be utilized. Accordingly, individual memory cells may include a material capable of being in two or more stable states to store a logic value.

As illustrated, an electrically isolating material 104 may separate the conductive access lines (e.g., word lines 110 and bitlines 112) of the bottom deck (e.g., deck 0) from bitline sockets 106 and word line sockets 108. For example, the memory cells 102 may be coupled with access and control circuitry for operation of the three-dimensional memory device 100 via the bitline sockets 106 and the word line sockets 108.

Examples of multi-deck or multi-layer memory architectures include multi-deck memory and 3D NAND memory. Different memory technologies have adopted different terminology. For example, a deck in some memory devices typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2X-layer NAND device). The term “deck” will be used throughout this disclosure to describe a layer, a tier, or a similar portion of a three-dimensional memory.

The techniques described herein typically may include memory devices with one or multiple layers or multiple decks of memory cells.

As will be described in greater detail below, systems, apparatuses and methods of some implementations herein provide for technology that forms an extended bitline air gap structure for a 3D-NAND memory structure, in some examples.

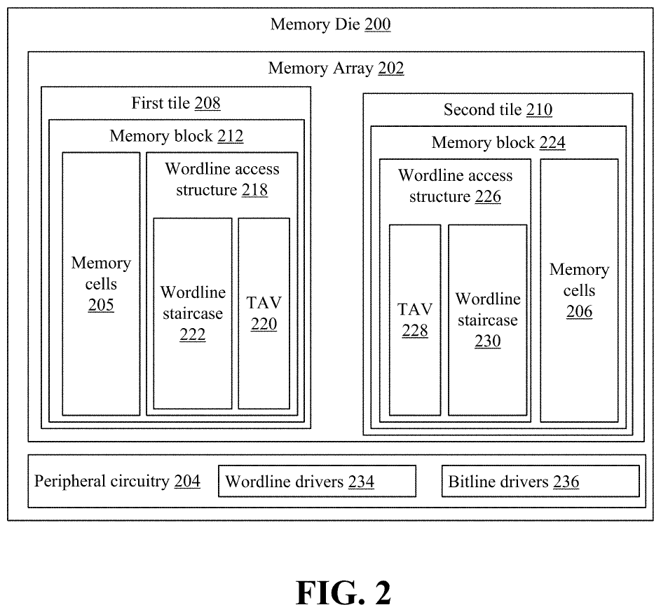

FIG. 2 illustrates a simplified example side view diagram of a memory die 200, consistent with one embodiment of the present disclosure. The memory die 200 includes a 3D flash memory architecture and utilizes a word line bridge to share word line access structures between two tiles of a memory array, according to one embodiment.

The memory die 200 includes a memory array 202 and peripheral circuitry 204, according to one embodiment. The memory array 202 includes memory cells 205 and memory cells 206 that are accessed (e.g., read/write) with the peripheral circuitry 204, according to one embodiment. The peripheral circuitry 204 is fabricated at least partially under the memory array 202 in the memory die 200, for example, using complementary metal-oxide semiconductor (CMOS) under array (CuA) fabrication techniques, according to one embodiment.

The memory array 202 is segmented into a first tile 208 and a second tile 210, according to one embodiment. Although two tiles are illustrated and described the memory array 202 may be segmented into 10's or 100's of tiles to facilitate access and operation of the memory array 202, according to one embodiment. The first tile 208 includes a memory block 212, which includes the memory cells 205 and word line access structures 218, according to one embodiment. The word line access structures 218 include through array vias 220 and a word line staircase 222 (or other worldline access structure), according to one embodiment. The through array vias 220 connect word lines for the memory cells 205 to the peripheral circuitry 204, under the memory array 202, according to one embodiment. The word line staircase 222 represents a word line staircase structure that may be used to connect the word lines of the memory cells 205 to metal contacts for connection to upper metal levels, according to one embodiment. The word line access structures 218 are illustrated disproportionately large in comparison to the memory cells 205 for illustration purposes. In practice, the memory cells 205 may occupy a significantly larger area in the memory array that the word line access structures 218, according to one embodiment.

The second tile 210 includes a memory block 224, which includes the memory cells 206 and word line access structures 226, according to one embodiment. The word line access structures 226 include through array vias 228 and a word line staircase 230, according to one embodiment. The through array vias 228 pass through the memory block 224 to couple upper metal levels to the peripheral circuitry 204, according to one embodiment. The word line staircase 230 provides landings and/or a structure to which metal contacts connect the word lines of the memory cells 206 to upper metal levels that are on top of or above the memory array 202, according to one embodiment.

The peripheral circuitry 204 includes word line drivers 234 and bitline drivers 236 that drive word lines and bitlines for the memory array 202, in some implementations. In some examples, such peripheral circuitry 204 is fabricated at least partially under the memory array 202 in the memory die 200, for example, using complementary metal-oxide semiconductor (CMOS) under array (CuA) fabrication techniques, in some examples.

As will be described in greater detail below, systems, apparatuses and methods of some implementations herein provide for technology that forms an extended bitline air gap structure for a 3D-NAND memory structure, in some examples.

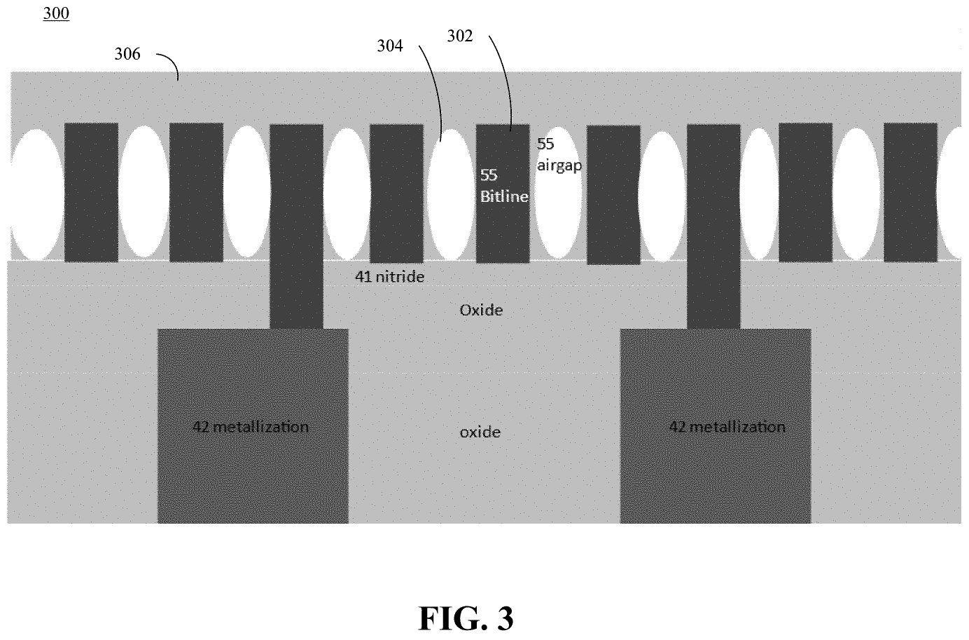

FIG. 3 illustrates a current memory device 300 with bitline airgaps 302 interspersed between bitline contacts 304 and capped by a dielectric layer 306. As illustrated, the bitline airgaps 302 do not extend past the bitline contacts 304.

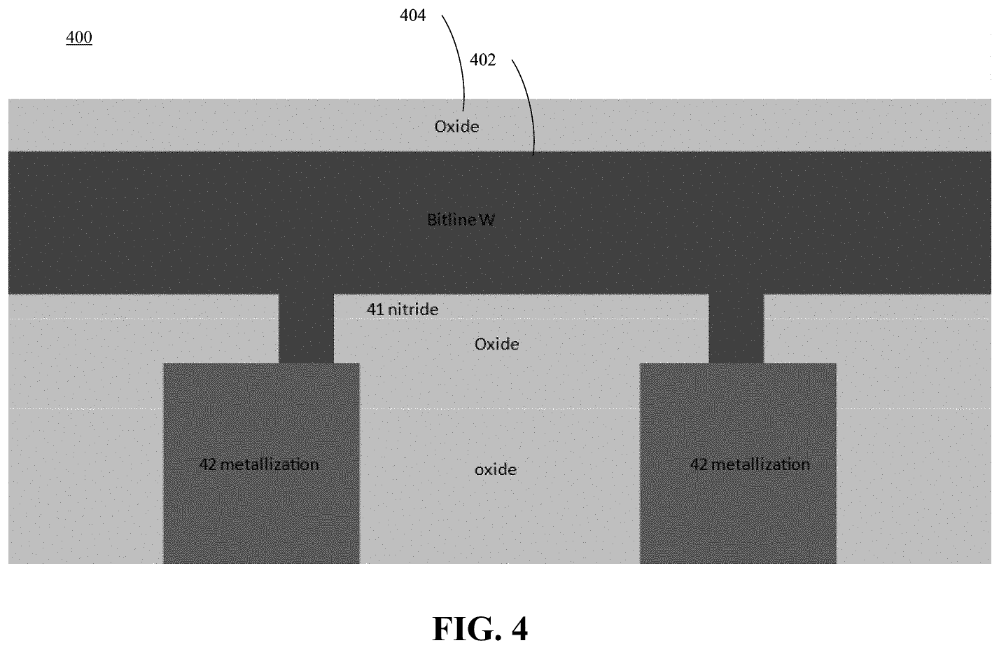

Conversely, as will be illustrated in the implementation of FIGS. 4, 5, and 6 below, an extended bitline air gap may be formed in some implementations described herein.

FIG. 4 illustrates an example of a memory device 400 with a bitline layer 402 according to an embodiment at a certain stage of formation.

For example, such a bitline layer 402 may be deposited above a substrate of a memory die. In some examples, the bitline layer includes tungsten, aluminum, copper, molybdenum, the like, or combinations thereof.

In some examples, the bitline layer 402 may be capped with a dielectric layer 404. In some examples, the dielectric layer includes oxide, nitride, the like, and/or combinations thereof.

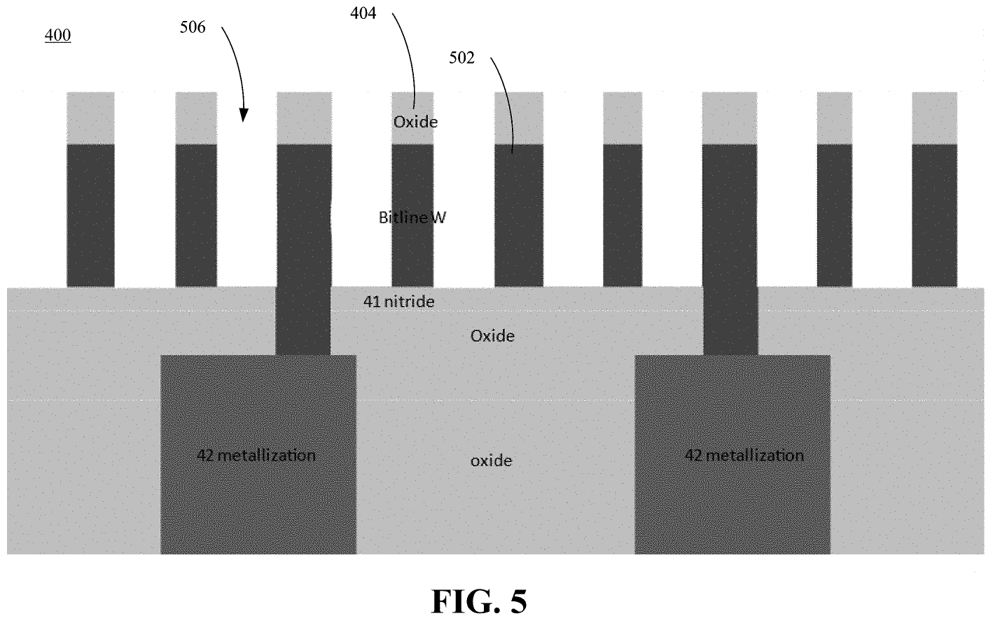

FIG. 5 illustrates an example of the memory device 400 with a bitline structure according to an embodiment at a certain stage of formation.

For example, the dielectric layer 404 and the bitline layer (illustrated in FIG. 4) may be patterned and etched to create bitline contacts 502 and openings 506 between adjacent bitline contacts 502. In some implementations, the bitline contacts are constructed through a subtractive bitline formation process via an etch.

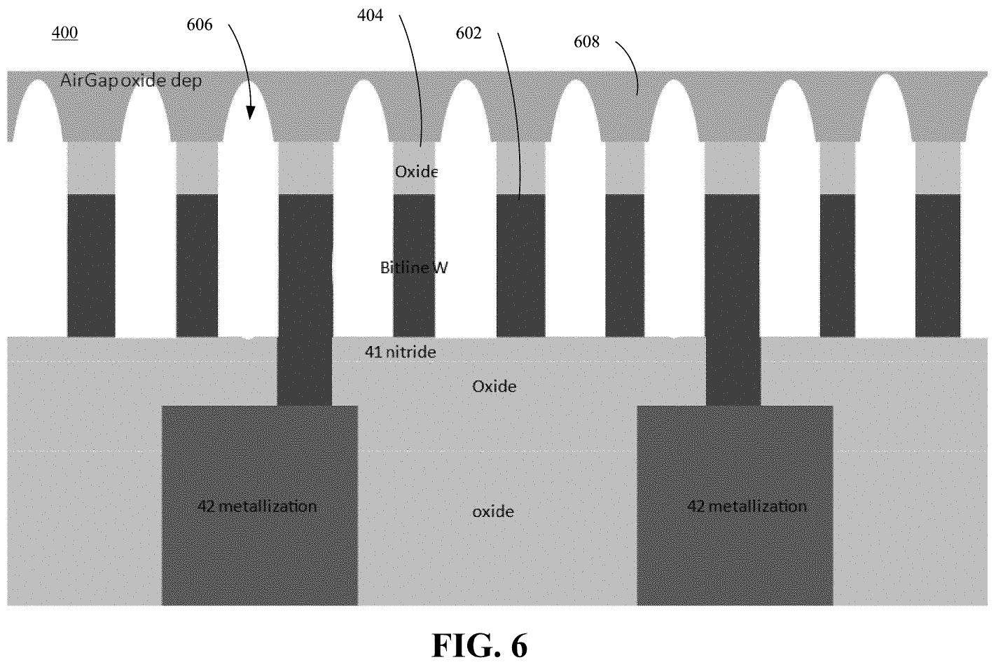

FIG. 6 illustrates an example of the memory device 400 with a bitline structure 602 according to an embodiment at a certain stage of formation.

For example, an air gap dielectric layer 608 may be deposited to form an air gap 606 between adjacent bitline contacts.

In some examples, the air gap dielectric layer 608 includes an air gap dielectric, an air gap nitride, an air gap oxide, an air gap silicon nitride, an air gap carbon doped silicon nitride, the like, and/or combinations thereof.

In some implementations, the air gap dielectric layer 608 is deposited to form an air gap 606 between adjacent bitline contacts 602 where the air gap 606 has a height dimension that extends past a height dimension of the bitline contacts 602 (e.g., as may be caused by non-conformal deposition properties of the air gap dielectric layer 608). Additionally, or alternatively, the air gap dielectric layer 608 is deposited to form an air gap 606 between adjacent bitline contacts 602 where the air gap 606 extends into the air gap dielectric layer 608. Additionally, or alternatively, the air gap dielectric layer 608 is deposited to form an air gap 606 between adjacent bitline contacts 602 where the height dimension of the air gap 606 extends past a height dimension of the dielectric layer 608.

In some examples, the air gap 606 height dimension is adjustable by adjusting the thickness of the dielectric layer 404.

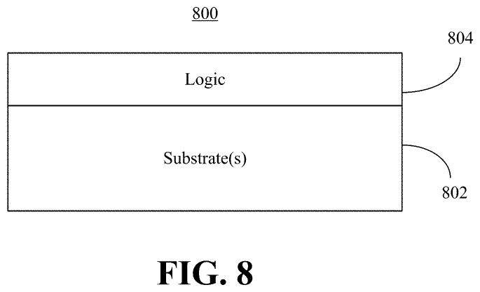

In some implementations, the memory device 400 may be implemented as a memory die (e.g., 3D-NAND memory, the like, and/or combinations thereof). Such a memory die (e.g., see, FIG. 8 below) may include a memory array and a bitline structure coupled to the memory array. The bitline structure including: a plurality of bitline contacts; a dielectric layer position above the plurality of bitline contacts; an air gap dielectric layer positioned above the plurality of bitline contacts; and an air gap positioned between adjacent bitline contacts of the plurality of bitline contacts, where the air gap has a height dimension that extends past a height dimension of the plurality of bitline contacts.

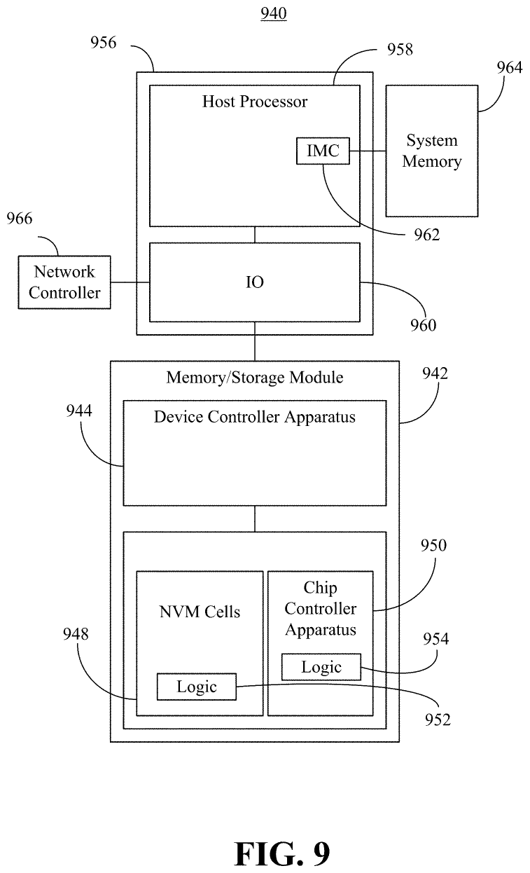

In some examples, the memory device 400 may be implemented as a solid state drive (SSD). The solid state drive (SSD) including: a memory controller; and a memory device coupled to the memory controller (e.g., see, FIG. 9 below).

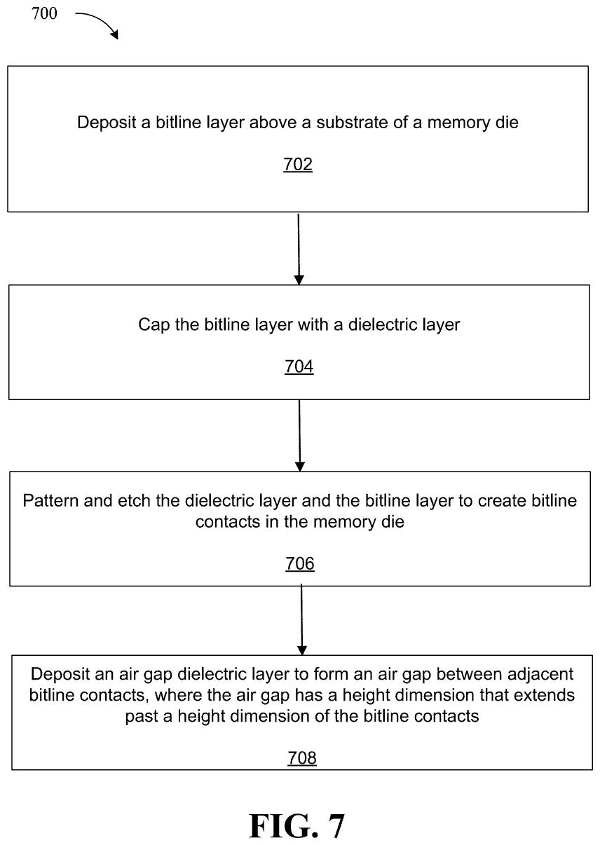

FIG. 7 is a flowchart of an example method 700 of forming a memory device according to an embodiment. The method 700 may generally be implemented to form a memory device, such as, for example, the memory device 600 (e.g., see FIG. 6).

Illustrated processing block 702 provides for depositing a bitline layer. For example, such a bitline layer may be deposited above a substrate of a memory die.

In some examples, the bitline layer includes tungsten, aluminum, copper, molybdenum, the like, or combinations thereof.

Illustrated processing block 704 provides for capping the bitline layer. For example, the bitline layer may be capped with a dielectric layer.

In some examples, the dielectric layer includes oxide, nitride, the like, and/or combinations thereof.

Illustrated processing block 706 provides for patterning and etching the dielectric layer and the bitline layer. For example, the dielectric layer and the bitline layer may be patterned and etched to create bitline contacts in the memory die.

In some implementations, the bitline contacts are constructed through a subtractive bitline formation process via the etch

Illustrated processing block 708 provides for depositing an air gap dielectric layer. For example, such an air gap dielectric layer may be deposited to form an air gap between adjacent bitline contacts.

In some examples, the air gap dielectric layer includes an air gap dielectric, an air gap nitride, an air gap oxide, an air gap silicon nitride, an air gap carbon doped silicon nitride, the like, and/or combinations thereof.

In some implementations, the air gap dielectric layer is deposited to form an air gap between adjacent bitline contacts where the air gap has a height dimension that extends past a height dimension of the bitline contacts. Additionally, or alternatively, the air gap dielectric layer is deposited to form an air gap between adjacent bitline contacts where the air gap extends into the air gap dielectric layer. Additionally, or alternatively, the air gap dielectric layer is deposited to form an air gap between adjacent bitline contacts where the height dimension of the air gap extends past a height dimension of the dielectric layer.

Additional details regarding the various implementations of the method 700 are discussed below with regard to FIGS. 8 and 9.

FIG. 8 shows a semiconductor apparatus 800 (e.g., chip, die, and/or package). The illustrated apparatus 800 includes one or more substrates 802 (e.g., silicon, sapphire, gallium arsenide) and logic 804 (e.g., transistor array and other integrated circuit/IC components) coupled to the substrate(s) 802. In an embodiment, the logic 804 implements one or more aspects of a memory device 600 (e.g., see FIG. 6), already discussed.

In one example, the logic 804 includes transistor channel regions that are positioned (e.g., embedded) within the substrate(s) 802. Thus, the interface between the logic 804 and the substrate 802 may not be an abrupt junction. The logic 804 may also be considered to include an epitaxial layer that is grown on an initial wafer of the substrate 802.

Turning now to FIG. 9, a performance-enhanced computing system 940 is shown. In the illustrated example, a solid state drive (SSD) 942 includes a device controller apparatus 944 that is coupled to a NAND 946. The illustrated NAND 946 includes a memory device 948 having a set of multi-level NVM cells and logic 952 (e.g., transistor array and other integrated circuit/IC components coupled to one or more substrates containing silicon, sapphire and/or gallium arsenide), and a chip controller apparatus 950 that includes logic 954. The logic 954 may include one or more of configurable or fixed-functionality hardware.

The illustrated system 940 also includes a system on chip (SoC) 956 having a host processor 958 (e.g., central processing unit/CPU) and an input/output (I/O) module 960. The host processor 958 may include an integrated memory controller 962 (IMC) that communicates with system memory 964 (e.g., RAM dual inline memory modules/DIMMs). The illustrated IO module 960 is coupled to the SSD 942 as well as other system components such as a network controller 966.

In some embodiments, the NAND 946 implements one or more aspects of a memory device 600 (e.g., see FIG. 6), already discussed already discussed.

### Additional Notes and Examples

Example 1 includes a memory die including: a memory array; and a bitline structure coupled to the memory array. The bitline structure including: a plurality of bitline contacts; a dielectric layer position above the plurality of bitline contacts; an air gap dielectric layer positioned above the plurality of bitline contacts; and an air gap positioned between adjacent bitline contacts of the plurality of bitline contacts, where the air gap has an air gap height dimension that extends past a bitline contact height dimension of the plurality of bitline contacts.

Example 2 includes the memory die of Example 1, where the air gap extends into the air gap dielectric layer.

Example 3 includes the memory die of any one of Examples 1 to 2, wherein the air gap height dimension extends past a dielectric layer height dimension of the dielectric layer.

Example 4 includes the memory die of any one of Examples 1 to 3, where the plurality of bitline contacts include one or more of tungsten, aluminum, copper, and molybdenum.

Example 5 includes the memory die of any one of Examples 1 to 4, where the plurality of bitline contacts are constructed through a subtractive bitline formation process.

Example 6 includes the memory die of any one of Examples 1 to 5, where the memory die includes 3D-NAND memory.

Example 7 includes a solid state drive (SSD) including: a memory controller; and a memory device coupled to the memory controller. The memory device including: a memory array; and a bitline structure coupled to the memory array. The bitline structure including: a plurality of bitline contacts; a dielectric layer position above the plurality of bitline contacts; an air gap dielectric layer positioned above the plurality of bitline contacts; and an air gap positioned between adjacent bitline contacts of the plurality of bitline contacts, where the air gap has an air gap height dimension that extends past a bitline contact height dimension of the plurality of bitline contacts.

Example 8 includes the solid state drive (SSD) of Example 7, where the air gap extends into the air gap dielectric layer.

Example 9 includes the solid state drive (SSD) of any one of Examples 7 to 8, wherein the air gap height dimension extends past a dielectric layer height dimension of the dielectric layer.

Example 10 includes the solid state drive (SSD) of any one of Examples 7 to 9, where the plurality of bitline contacts include one or more of tungsten, aluminum, copper, and molybdenum.

Example 11 includes the solid state drive (SSD) of any one of Examples 7 to 10, where the plurality of bitline contacts are constructed through a subtractive bitline formation process.

Example 12 includes the solid state drive (SSD) of any one of Examples 7 to 11, where the device includes 3D-NAND memory.

Example 13 includes a method including: patterning and etching a dielectric layer and a bitline layer to create bitline contacts in a memory die; and depositing an air gap dielectric layer to form an air gap between adjacent bitline contacts, and where the air gap has an air gap height dimension that extends past a bitline contact height dimension of the bitline contacts.

Example 14 includes the method of Example 13, where the air gap extends into the air gap dielectric layer.

Example 15 includes the method of any one of Examples 13 to 14, where the height dimension of the air gap extends past a dielectric layer height dimension of the dielectric layer.

Example 16 includes the method of any one of Examples 13 to 15, further including: depositing the bitline layer above a substrate of the memory die.

Example 17 includes the method of Example 16, further including: capping the bitline layer with the dielectric layer.

Example 18 includes the method of any one of Examples 13 to 17, where the bitline layer includes one or more of tungsten, aluminum, copper, and molybdenum.

Example 19 includes the method of any one of Examples 13 to 18, where the bitline contacts are constructed through a subtractive bitline formation process via the etching.

Example 20 includes the method of any one of Examples 13 to 19, where the memory die includes 3D-NAND memory.

Example 21 includes a machine-readable storage comprising machine-readable instructions, which when executed, implement a method or realize an apparatus as claimed in any preceding claim.

Example 22 includes an apparatus comprising means for performing the method of any one of Examples 13 to 20.

Technology described herein therefore provides the capability to form an extended bitline air gap structure for a 3D-NAND memory structure, in some examples. Advantageously, a higher bitline airgap, such as those disclosed herein, improve bitline capacitance. Accordingly, such techniques provide improved performance through improved High Input/Output speed and/or decreased power consumption. More specifically, reducing the bitline capacitance typically results in higher 3D NAND program latency (tPROG) speed.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A memory die comprising:
a memory array; and
a bitline structure coupled to the memory array, the bitline structure comprising:
a plurality of bitline contacts;
a dielectric layer position above the plurality of bitline contacts;
an air gap dielectric layer positioned above the plurality of bitline contacts; and
an air gap positioned between adjacent bitline contacts of the plurality of bitline contacts, wherein the air gap has an air gap height dimension that extends past a bitline contact height dimension of the plurality of bitline contacts.

2. The memory die of claim 1, wherein the air gap extends into the air gap dielectric layer.

3. The memory die of claim 1, wherein the air gap height dimension extends past a dielectric layer height dimension of the dielectric layer.

4. The memory die of claim 1, wherein the plurality of bitline contacts comprise one or more of tungsten, aluminum, copper, and molybdenum.

5. The memory die of claim 1, wherein the plurality of bitline contacts are constructed through a subtractive bitline formation process.

6. The memory die of claim 1, wherein the memory die comprises 3D-NAND memory.

7. A solid state drive (SSD) comprising:
a memory controller; and
a memory device coupled to the memory controller, the memory device comprising:
a memory array; and
a bitline structure coupled to the memory array, the bitline structure comprising:
a plurality of bitline contacts;
a dielectric layer position above the plurality of bitline contacts;
an air gap dielectric layer positioned above the plurality of bitline contacts; and
an air gap positioned between adjacent bitline contacts of the plurality of bitline contacts, wherein the air gap has an air gap height dimension that extends past a bitline contact height dimension of the plurality of bitline contacts.

8. The solid state drive (SSD) of claim 7, wherein the air gap extends into the air gap dielectric layer.

9. The solid state drive (SSD) of claim 7, wherein the air gap height dimension extends past a dielectric layer height dimension of the dielectric layer.

10. The solid state drive (SSD) of claim 7, wherein the plurality of bitline contacts comprise one or more of tungsten, aluminum, copper, and molybdenum.

11. The solid state drive (SSD) of claim 7, wherein the plurality of bitline contacts are constructed through a subtractive bitline formation process.

12. The solid state drive (SSD) of claim 7, wherein the memory device comprises 3D-NAND memory.

13. A method comprising:
patterning and etching a dielectric layer and a bitline layer to create bitline contacts in a memory die; and
depositing an air gap dielectric layer to form an air gap between adjacent bitline contacts, and wherein the air gap has an air gap height dimension that extends past a bitline contact height dimension of the bitline contacts.

14. The method of claim 13, wherein the air gap extends into the air gap dielectric layer.

15. The method of claim 13, wherein the air gap height dimension extends past a dielectric layer height dimension of the dielectric layer.

16. The method of claim 13, further comprising:
depositing the bitline layer above a substrate of the memory die.

17. The method of claim 16, further comprising:
capping the bitline layer with the dielectric layer.

18. The method of claim 13, wherein the bitline layer comprises one or more of tungsten, aluminum, copper, and molybdenum.

19. The method of claim 13, wherein the bitline contacts are constructed through a subtractive bitline formation process via the etching.

20. The method of claim 13, wherein the memory die comprises 3D-NAND memory.
